(19) United States
(12) Patent Application Publication
(10) Pub. No.: US 2023/0268753 A1
(43) Pub. Date: Aug. 24, 2023

(54) INTELLIGENT BATTERY CHARGING BASED ON HISTORY

(71) Applicant: Lenovo (United States) Inc., Morrisville, NC (US)

(72) Inventors: Bouziane Yebka, Apex, NC (US); Jeremy Robert Carlson, Cary, NC (US); Philip John Jakes, Durham, NC (US); Tin-Lup Wong, Chapel Hill, NC (US)

(21) Appl. No.: 17/676,500

(22) Filed: Feb. 21, 2022

(51) Int. Cl. H02J 7/00; G01R 31/367; G01R 31/385

(52) U.S. Cl. CPC H02J 7/00712; G01R 31/367; G01R 31/385; H02J 7/005; H02J 7/00036

(57) ABSTRACT

A method includes detecting a request for a battery charge, receiving multiple battery parameters representative of battery charging history, determining a charging parameter to increase battery life as a function of the multiple battery parameters, and charging the battery in accordance with the charging parameter.

### BACKGROUND

Charging batteries can be performed by providing current to the battery. The charge provided may be delivered by predetermined actions with hard coded thresholds based on the sensed charge. The delivered charge may not be conducive to optimizing the life span of the battery being charged.

### SUMMARY

A method includes detecting a request for a battery charge, receiving multiple battery parameters representative of battery charging history, determining a charging parameter to increase battery life as a function of the multiple battery parameters, and charging the battery in accordance with the charging parameter.

### BRIEF DESCRIPTION OF THE DRAWINGS

FIG. 1 is block diagram of a system to control charging of a battery according to an example embodiment.

FIG. 2 is a flowchart of a computer implemented method for charging a battery according to an example embodiment.

FIG. 3 is a block diagram illustrating a system to determine one or more charging parameters according to an example embodiment.

FIG. 4 is a timing diagram illustrating the functions performed to charge a battery in a manner that optimizes the number of cycles provided by battery according to an example embodiment.

FIG. 5 is a chart illustrating a history of various battery parameters that may be stored over the life of the battery according to an example embodiment.

FIG. 6 is a flowchart illustrating a computer implemented method of selecting a charging profile for use in charging a battery according to an example embodiment.

FIGS. 7A, 7B, 7C, 7D, 7E, and 7F show examples of multiple different charging profiles which may be selected according to an example embodiment.

FIGS. 8A, 8B, and 8C illustrate how the use of health condition-based profiles can extend the number of charge and discharge cycles of a battery to extend useful battery life according to an example embodiment.

FIG. 9 is a block schematic diagram of a computer system to implement one or more example embodiments.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software in one embodiment. The software may consist of computer executable instructions stored on computer readable media or computer readable storage device such as one or more non-transitory memories or other type of hardware-based storage devices, either local or networked. Further, such functions correspond to modules, which may be software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system, turning such computer system into a specifically programmed machine.

The functionality can be configured to perform an operation using, for instance, software, hardware, firmware, or the like. For example, the phrase “configured to” can refer to a logic circuit structure of a hardware element that is to implement the associated functionality. The phrase “configured to” can also refer to a logic circuit structure of a hardware element that is to implement the coding design of associated functionality of firmware or software. The term “module” refers to a structural element that can be implemented using any suitable hardware (e.g., a processor, among others), software (e.g., an application, among others), firmware, or any combination of hardware, software, and firmware. The term, “logic” encompasses any functionality for performing a task. For instance, each operation illustrated in the flowcharts corresponds to logic for performing that operation. An operation can be performed using, software, hardware, firmware, or the like. The terms, “component,” “system,” and the like may refer to computer-related entities, hardware, and software in execution, firmware, or combination thereof. A component may be a process running on a processor, an object, an executable, a program, a function, a subroutine, a computer, or a combination of software and hardware. The term, “processor,” may refer to a hardware component, such as a processing unit of a computer system.

Furthermore, the claimed subject matter may be implemented as a method, apparatus, or article of manufacture using standard programming and engineering techniques to produce software, firmware, hardware, or any combination thereof to control a computing device to implement the disclosed subject matter. The term, “article of manufacture,” as used herein is intended to encompass a computer program accessible from any computer-readable storage device or media. Computer-readable storage media can include, but are not limited to, magnetic storage devices, e.g., hard disk, floppy disk, magnetic strips, optical disk, compact disk (CD), digital versatile disk (DVD), smart cards, flash memory devices, among others. In contrast, computer-readable media, i.e., not storage media, may additionally include communication media such as transmission media for wireless signals and the like.

Methods of charging batteries include simply providing current at a set voltage until the battery is in a full state of charge (SOC.) Some charging methods may reduce the charge voltage over time in a pre-programmed manner in an attempt to increase the number of cycles and hence the usable life of the battery. While such reductions in charge voltage can extend the life in some batteries, the same reductions may actually decrease the life other batteries that have different histories of use. The differences between batteries may include the number of cycles already endured, the length of time the battery was stored, minimum, SOC. and maximum temperature differences.

Intelligent battery charging may be performed as a function of an assessment of the battery condition, considering one or more parameters representing an actual state of the battery and history of the battery before a charging and discharging cycle. Such parameters may include the voltage, resistance, temperature, and state of health (state of charge (SOC), age, cycle life) before charging and discharging. The charge provided may be optimized to minimize any stress that may affect the battery’s longevity in terms of the cycle life measured by the number of charging and discharging cycles a battery can endure before performance degrades below an acceptable level.

The assessment may be done in a battery pack, in a device that battery is providing power for, in a charging device, or in the cloud. The cumulative generated historical data may be logged in the battery pack, or the device, or the cloud along with an associated battery pack ID to enable the data to be accessed.

One or more benefits of intelligent battery charging may include more accurate control based on each battery condition and history, battery life extension, particularly for high energy density chemistry, minimizing the capacity loss, early detection of any abnormality via analysis of the historical parameters, and a better user experience.

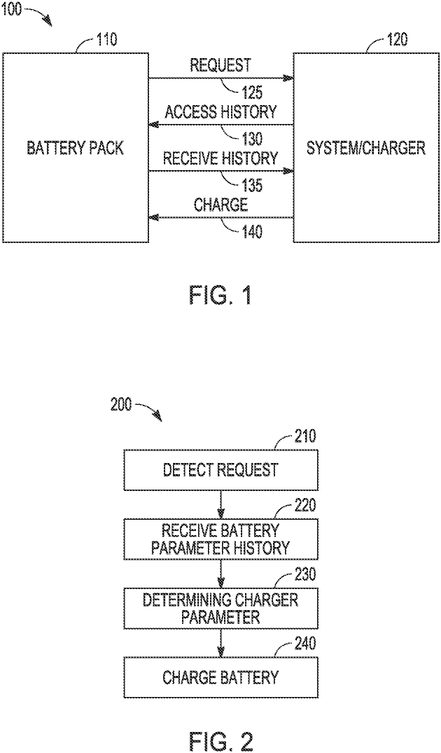

FIG. 1 is block diagram of a system 100 to control charging of a battery, such as a battery pack 110 by a system/charger 120. The system/charger 120 may be a laptop computer or other device, such as a cellular phone, touchpad, or other electronic device using a battery that is capable of interacting with the battery pack 110 to receive power from the battery pack 110 and charge the battery pack 110. A battery cycle is one sequence of a charge and a discharge of the battery pack 110. The life of the battery pack may be measured in the number of cycles that can occur before the battery pack can no longer hold a desired amount of charge or provide a desired level of voltage or current.

The battery pack 110 may request a charge at 125 from the system/charger 120. The request may include a requested current IR for charging. The request 125 may be initiated when the system/charger 120 is plugged into a power source. In response to the request 125, the system/charger 120 may access a parameter history of the battery pack 110. The history may be maintained by the battery pack in one example and may include historic information regarding temperature, cycles, calendar aging, state of charge (SOC - a percentage of the original battery capacity), and other parameters related to the state of the battery pack 110 over the current life of the battery pack 110. In further examples, the history may be stored in the system/charger 120, or a remote memory device and accessed via a unique battery pack 110 ID.

The parameter history is received by the system/charger 120 at 135 and is analyzed by the system/charger 120 to generate one or more charge parameters, such a charging current IC, that are designed to charge the battery pack 110 in a manner that increases the number of cycles the battery pack 110 can be charged and discharged. Generation of the one or more charge parameters may be done by comparing the parameter history to ranges of parameter values associated with one or more charging profiles and selecting the charging profile that most closely matches the parameter history values. Similarity measures between respective values may alternatively be used.

The charging profile may specify one or more of current and voltage for use in charging the battery pack 100, which is performed at 140. In a further example, the parameter history may be further analyzed to generate an assessment, which may then be compared to assessments associated with the charging profiles. The assessment may include aggregations of values in the parameter history, including one or more of actual values, maximum values, minimum values, averages, and predictions of values inferred from other values.

In one example, a machine learning model for a particular model of a battery or battery pack may be trained on data collected from use of multiple ones of the battery pack model. The data collected for each battery pack may include multiple battery parameter history values, battery assessments based on the parameter history values, and charging parameters used over the life of the battery pack. The battery packs with the longest cycle lives may be used for the training, with the output of the model predicting the charging parameter to use.

FIG. 2 is a flowchart of a computer implemented method 200 for charging a battery. Method 200 begins by detecting a request for a battery charge at operation 210. The request may include a requested current IR. Multiple battery parameters representative of battery charging history are received at operation 220. The multiple battery parameters may be stored on a storage device on the battery or may be stored and requested from remote storage device that includes an ID for the battery associate with the history.

At operation 230, one or more charging parameters are determined as a function of the multiple battery parameters. The charging parameters are determined to increase battery life, such as by increasing the number of charging and discharging cycles the battery can be subjected to prior to no longer being able to hold a desired charge or provide a desired or required current or voltage. At operation 240, the battery charged in accordance with the one or more charging parameters. The one or more charging parameters may include a current level, and voltage level, or both current and voltage levels.

The one or more charging parameters may be determined by matching the battery parameters to one of multiple charging profiles having associated charging profile battery parameters using a similarity measure. The similarity measure is designed to find the charging profile having the closest matching battery parameter. Many different similarity measures may be used, including at least one of cosine similarity, Manhattan distance, Euclidean distance, Minkowski distance, and Jaccard similarity. Different weights may also be applied to the battery parameters. Such weights may be determined empirically by using different charging profiles for multiple same batteries with different battery parameter histories and determining which battery parameters are more important.

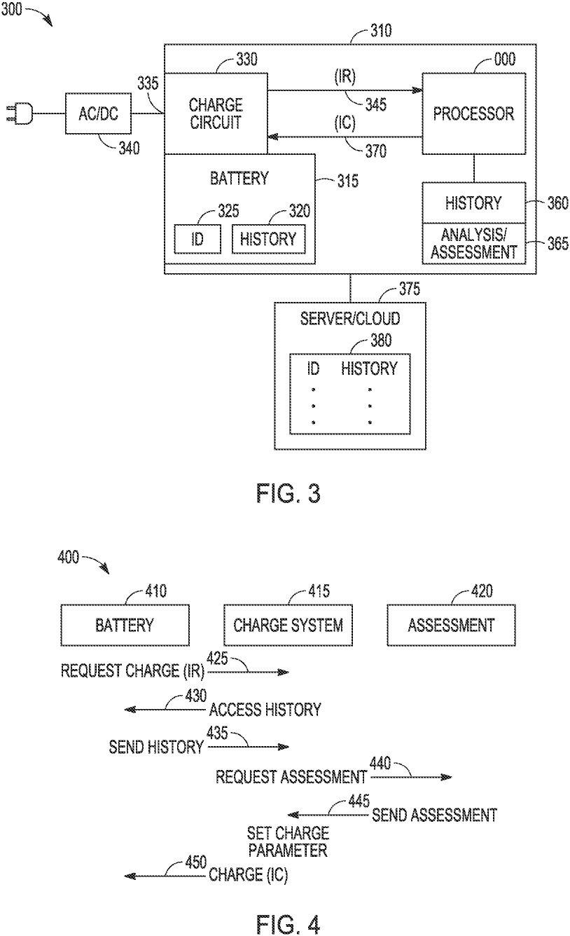

FIG. 3 is a block diagram illustrating a system 300 to determine one or more charging parameters. System 300 includes an electronic device 310, such as laptop computer that includes a battery 315. Battery 315 may be a rechargeable battery, such as Li-ion battery or battery pack. Battery 315 includes circuitry to collect and store a history 320 of various parameters collected over cycles of charging and discharging battery 315. An ID 325 of the battery 315 may also be stored.

Device 310 also includes a charge circuit 330 coupled to a power in port 335 for connecting via a charging cable 340 that may include an AC to DC converter. The charging cable 340 may plug into a power source. The battery 315 may include two or more conductors coupled to the charge circuit 330 for both receiving power and providing power to the device 310.

The battery may request a charging current IR via line 345 coupled to a processor 350. The processor may read the history 320 and optionally the ID 325. The history is copied into a memory 355 at 360. Analysis/assessment code 365 is used by the processor 350 to calculate or otherwise determine one or more charging parameters, such as a charge current IC, which is provided to the charge circuit at 370. The charge circuit proceeds to charge the battery 315 utilizing the one or more charging parameters.

In a further example, the history may be provided to or obtained from a remote server 375 from a copy stored at 380 that includes the battery 315 ID 325 corresponding to the history. The server 375 may store histories of multiple batteries that may be periodically updated with the history 320 stored on the battery 315. The multiple histories may be used to refine methods used to determine the one or more charging parameters.

FIG. 4 is a timing diagram 400 illustrating the functions performed to charge a battery 410 in a manner that optimizes the number of cycles provided by battery 410. Three components are illustrated in diagram 400, including the battery 410, a charge system 415, and an assessment function 420. The charge system 415 may include both a charging circuit and a processing circuity in various examples. The assessment component may be performed by the processing circuity in a system containing the battery 410, or by a remote system.

In response to a power source being detected as available, battery 410 may request a charge current, IR, at 425 from the charge system 415. The charge system will then access the history at 430. The history is shown as being accessed from battery 410, but may alternatively be accessed from memory, either in charge system 415 or remote cloud-based storage.

The history is sent to the charge system at 435, and an assessment 420 of the battery is requested at 440. The assessment 420 may be performed via processing resources in the charge system or remote processing resources, such as cloud-based resources. The assessment is provided to the charge system 415 at 445. One or more parameters from the assessment are used to set charging parameters which are used to provide a charge current (IC) at 450 to the battery 410.

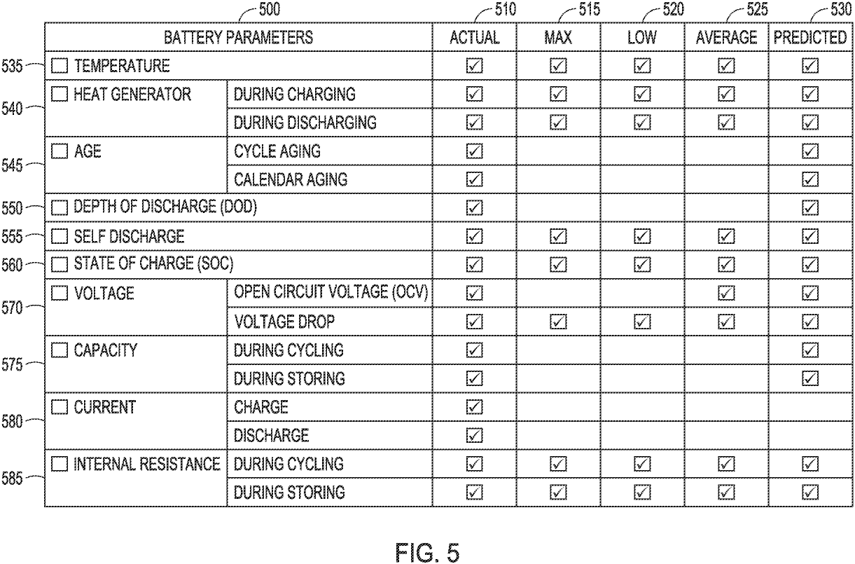

FIG. 5 is a chart illustrating a history of various battery parameters 500 that may be stored over the life of the battery. A diagnosis or assessment of battery parameters may also be included. An indication of the values that are measured and analyzed is provided as a check box for actual value 510, maximum value 515, minimum or low value 520. average value 525, and predicted value 530.

The parameters may include one or more of temperature 535, heat generation 540 for both charging and discharging, age 545 for both cycle aging and calendar aging, depth of discharge (DOD) 550, self-discharge 555, state of charge (SOC) 560, voltage 570 for both open circuit voltage (OCV) and voltage drop, capacity 575 during cycling and during storage, current 580 during charge and discharge, and internal resistance 585 during cycling and during storage. Smart batteries contain circuitry that cam measure the actual values, while analysis of the historical actual values can be used to generate the maximum value 515, minimum or low value 520, average value 525, and predicted value 530.

Three different batteries of the same model may have very different assessments. For example, a first battery may have an assessment generated from the history that includes 500 cycles, stored for 6 months, a minimum temperature of 10° C., a maximum temperature of 45° C., and an SOC of 30%. A second battery may have an assessment generated from the history that includes 2 cycles, stored for 1 month, a minimum temperature of 20° C., a maximum temperature of 25° C., and an SOC of 30%. A third battery may have an assessment generated from the history that includes 900 cycles, stored for 15 months, a minimum temperature of 0° C., a maximum temperature of 55° C., and an SOC of 30%. Even though each has the same SOC, each should be charged differently to extend their life. The charge condition may be optimized by selecting the profile that minimizes stress that may affect the battery’s longevity. In one example, even the current temperature of the charger, such as 25° C. may be taken into account in selecting the charging profile.

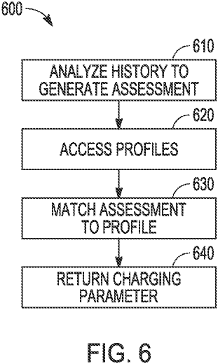

FIG. 6 is a flowchart illustrating a computer implemented method 600 of selecting a charging profile for use in charging a battery. Method 600 begins at operation 610 by generating a battery assessment as a function of the multiple battery parameters that were received. The battery assessments may include selected values for parameters from the history. The values may include actual values and values calculated from the history of actual values. In one example, the assessments include values for the historical number of charging and discharging cycles of the battery.

In one example, the battery assessment includes values for one or more of actual calendar aging, predicted calendar aging, temperature ranges for actual, maximum, minimum, average, and predicted, state of charge ranges for actual, maximum, minimum, average, and predicted. In one example, the assessment includes temperature, voltage, SOC, cycle number, and resistance for use in selecting a charging profile.

Multiple battery charging profiles having corresponding battery assessments may be accessed at operation 620. The battery assessments associated with charging profiles may include ranges for values. The generated battery assessment is matched to one of multiple charging profiles at operation 630. The matching may be performed using a similarity measure between the battery assessment and the assessments associated with the charging profiles. The similarity measure may include one or more of cosine similarity, Manhattan distance, Euclidean distance, Minkowski distance, and Jaccard similarity.

In further examples where the assessments for the profiles include ranges of values, the battery assessments are compared to determine how many values are within the ranges of each profile associated assessment. The profile assessment with the most values may be selected. Parameters may be weighted in further examples, with most relevant parameters weighted highest to provide a weighted count.

One or more battery charging parameters are selected from the matching profile and returned for use in charging the battery at operation 640.

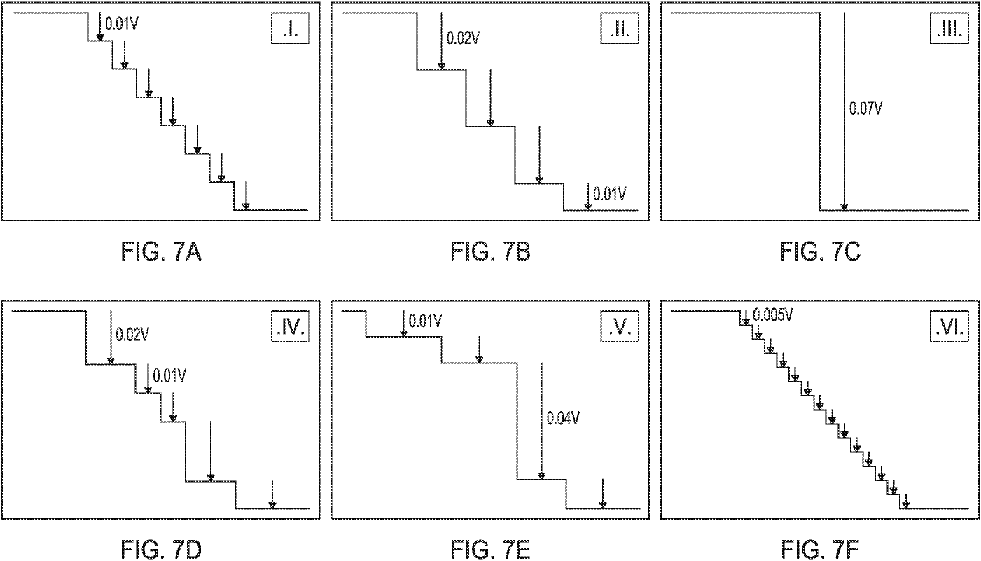

FIGS. 7A, 7B, 7C, 7D, 7E, and 7F show examples of multiple different charging profiles which may be selected. Each charging profile is shown as a voltage charging parameter for a charging cycle over the life of the battery. Generally, charging cycles early in the life of the battery occur at the highest voltage, such as 4.5 to 4.2 volts. The profile represents multiple voltage drops for the voltage parameter over the life of the battery. The drops may be constant, such as 0.01 V as shown in FIG. 7A. FIG. 7B shows drops of 0.02 V for the first three drops, and 0.01 V for a fourth and final voltage drop towards the end of the useful life of the battery. FIG. 7C shows a single voltage drop of 0.07 V about halfway through the useful life of the battery. FIGS. 7D and 7E show different voltage drops over time, with one drop of 0.04 V in FIG. 7E. FIG. 7F shows a series of smaller voltage drops of 0.005 V over time occurring much more rapidly than the other profiles shown. Each of these profiles may be used to optimize charging and discharging parameters based on the condition of the battery as reflected in the history. Such health condition-based profiles help extend the life of a battery based on the actual history of the battery.

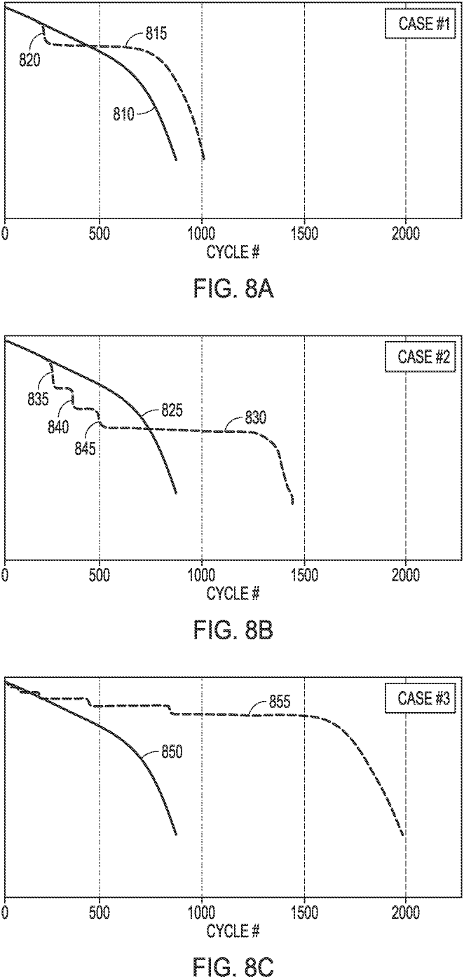

FIGS. 8A, 8B, and 8C illustrate how the use of health condition-based profiles can extend the number of charge and discharge cycles of a battery to extend useful battery life using prophetic examples. The vertical axis represents the remaining capacity of the battery, with the horizontal axis representing the number of cycles. Two curves are shown in each figure, with the solid line representing the capacity of the battery using prior charging methods. The broken line represents the use of health condition-based profile for charging.

The charging profiles may be determined based on empirical evidence obtain from testing batteries. Several factors affect the life of a battery. Use partial-discharge cycles, such as using only 20% or 30% of the battery capacity before recharging may extend cycle life considerably. Profiles may be selected based on these factors and correlated to assessments of histories.

As a general rule, 5 to 10 shallow discharge cycles are equal to one full discharge cycle. Although partial-discharge cycles can number in the thousands, keeping the battery in a fully charged state also shortens battery life. Avoiding full discharge cycles (down to 2.5 V or 3 V, depending on chemistry) may help extend battery life.

Avoiding charging batteries to 100% capacity can also help extend battery life. This can be done by selecting a lower float voltage. Reducing the float voltage will increase cycle life and service life at the expense of reduced battery capacity. A 100-mV to 300-mV drop in float voltage can increase cycle life from two to five times or more. Li-ion cobalt chemistries are more sensitive to a higher float voltage than other chemistries. Li-ion phosphate cells typically have a lower float voltage than the more common Li-ion batteries.

Selecting a correct charge termination point can also help extend battery life. Selecting a charger that uses minimum charge-current termination (C/10 or C/x) can also extend battery life by not charging to 100% capacity. For example, ending a charge cycle when the current drops to C/5 is similar to reducing the float voltage to 4.1 V. In both instances, the battery is only charged to approximately 85% of capacity, which is an important factor in battery life.

Limiting the temperature of the battery may also extend battery life. Limiting battery-temperature extremes extends battery life, especially prohibiting charging below 0° C. Charging below 0° C. promotes metal plating at the battery anode, which can develop into an internal short, producing heat and making the battery unstable and unsafe. Many battery chargers have provisions for measuring battery temperature to assure charging does not occur at temperature extremes.

Avoiding high charge and discharge currents can also help extend battery life. High charge and discharge currents reduce cycle life. Some chemistries are more suited for higher currents such as Li-ion manganese and Li-ion phosphate. High currents place excessive stress on the battery.

Avoiding very deep discharges, such as below 2.0 V or below 2.5 V can also help extend battery life. Very deep discharges will quickly, permanently damage a Li-ion battery. Internal metal plating can occur causing a short circuit, making the battery unusable and unsafe. Most Li-ion batteries have protection circuitry within their battery packs that open the battery connection if the battery voltage is less than 2.5 V or exceeds 4.3 V, or if the battery current exceeds a predefined threshold level when charging or discharging.

In FIG. 8A, prior charging line 810 results in less than 1000 cycles being available for the battery. Line 815 represents health condition-based profile charging resulting in just over 1000 cycles until the remaining capacity decreased to an unacceptable level. Line 815 indicates that a drop in charging voltage, and a corresponding drop in capacity when fully charged, occurred at around 200 cycles is indicated at 820. The remaining capacity leveled off following this change, extending the number of cycles at that capacity level and also extending the useful life to over 1000 cycles.

In FIG. 8B, prior charging line 825 results in less than 1000 cycles being available for the battery. Line 830 represents health condition-based profile charging resulting in close to 1500 cycles. Line 830 indicates that several drops in charging voltage occurred at various numbers of cycles as indicated at 835, 840, and 845. The remaining capacity leveled off following the change at 845, extending the number of cycles at that capacity level and also extending the useful life to almost 1500 cycles.

In FIG. 8C, prior charging line 850 results in less than 1000 cycles being available for the battery. Line 855 represents health condition-based profile charging resulting in close to 2000 cycles. Line 855 indicates that several drops in charging voltage occurred at various numbers of cycles with the remaining capacity leveling off following each change, extending the number of cycles at that capacity level and also extending the useful life to almost 2000 cycles.

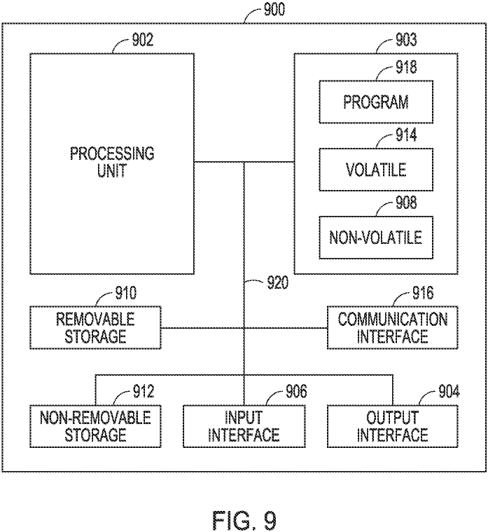

FIG. 9 is a block schematic diagram of a computer system 900 to increase battery life based on the history of the batter and for performing methods and algorithms according to example embodiments. All components need not be used in various embodiments.

One example computing device in the form of a computer 900 may include a processing unit 902, memory 903, removable storage 910, and non-removable storage 912. Although the example computing device is illustrated and described as computer 900, the computing device may be in different forms in different embodiments. For example, the computing device may instead be a smartphone, a tablet, smartwatch, smart storage device (SSD), or other computing device including the same or similar elements as illustrated and described with regard to FIG. 9. Devices, such as smartphones, tablets, and smartwatches, are generally collectively referred to as mobile devices or user equipment.

Although the various data storage elements are illustrated as part of the computer 900, the storage may also or alternatively include cloud-based storage accessible via a network, such as the Internet or server-based storage. Note also that an SSD may include a processor on which the parser may be run, allowing transfer of parsed, filtered data through I/O channels between the SSD and main memory.

Memory 903 may include volatile memory 914 and non-volatile memory 908. Computer 900 may include – or have access to a computing environment that includes - a variety of computer-readable media, such as volatile memory 914 and non-volatile memory 908, removable storage 910 and non-removable storage 912. Computer storage includes random access memory (RAM), read only memory (ROM), erasable programmable read-only memory (EPROM) or electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions.

Computer 900 may include or have access to a computing environment that includes input interface 906, output interface 904, and a communication interface 916. Output interface 904 may include a display device, such as a touchscreen, that also may serve as an input device. The input interface 906 may include one or more of a touchscreen, touchpad, mouse, keyboard, camera, one or more device-specific buttons, one or more sensors integrated within or coupled via wired or wireless data connections to the computer 900, and other input devices. The computer may operate in a networked environment using a communication connection to connect to one or more remote computers, such as database servers. The remote computer may include a personal computer (PC), server, router, network PC, a peer device or other common data flow network switch, or the like. The communication connection may include a Local Area Network (LAN), a Wide Area Network (WAN), cellular, Wi-Fi, Bluetooth, or other networks. According to one embodiment, the various components of computer 900 are connected with a system bus 920.

Computer-readable instructions stored on a computer-readable medium are executable by the processing unit 902 of the computer 900, such as a program 918. The program 918 in some embodiments comprises software to implement one or more methods described herein. A hard drive, CD-ROM, and RAM are some examples of articles including a non-transitory computer-readable medium such as a storage device. The terms computer-readable medium, machine readable medium, and storage device do not include carrier waves or signals to the extent carrier waves and signals are deemed too transitory. Storage can also include networked storage, such as a storage area network (SAN). Computer program 918 along with the workspace manager 922 may be used to cause processing unit 902 to perform one or more methods or algorithms described herein.

### EXAMPLES

1. A method includes detecting a request for a battery charge, receiving multiple battery parameters representative of battery charging history, determining a charging parameter to increase battery life as a function of the multiple battery parameters, and charging the battery in accordance with the charging parameter.

2. The method of example 1 wherein the request includes a requested current.

3. The method of any of examples 1-2 wherein the multiple battery parameters are stored on a storage device on the battery or a remote storage device.

4. The method of any of examples 1-3 wherein the charging parameter includes a current level.

5. The method of any of examples 1-4 wherein the charging parameter includes a voltage level.

6. The method of any of examples 1-5 wherein determining a charging parameter includes generating a battery assessment as a function of the multiple battery parameters and matching the battery assessment to one of multiple charging profiles.

7. The method of example 6 wherein the battery assessment includes values for a number of charging and discharging cycles of the battery.

8. The method of example 7 wherein the battery assessment includes values for one or more of actual calendar aging, predicted calendar aging, temperature ranges for actual, maximum, minimum, average, and predicted, state of charge ranges for actual, maximum, minimum, average, and predicted.

9. The method of any of examples 6-8 wherein matching is performed using a similarity measure between the battery assessment and the assessments associated with the charging profiles.

10. The method of example 9 wherein the similarity measure includes at least one of cosine similarity, Manhattan distance, Euclidean distance, Minkowski distance, and Jaccard similarity.

11. The method of any of examples 1-10 wherein determining a charging parameter includes matching the battery parameters to one of multiple charging profiles having associated charging profile battery parameters using a similarity measure.

12. The method of example 11 wherein the similarity measure includes at least one of cosine similarity, Manhattan distance, Euclidean distance, Minkowski distance, and Jaccard similarity.

13. The method of any of examples 1-12 wherein increasing battery life includes increasing the number of charging and discharging cycles of the battery.

14. A machine-readable storage device has instructions for execution by a processor of a machine to cause the processor to perform operations to perform a method. The operations include detecting a request for a battery charge, receiving multiple battery parameters representative of battery charging history, determining a charging parameter to increase battery life as a function of the multiple battery parameters, and charging the battery in accordance with the charging parameter.

15. The device of example 14 wherein the request includes a requested current, wherein the multiple battery parameters are stored on a storage device on the battery or a remote storage device, wherein the charging parameter comprises at least one of a current level and a voltage level.

16. The device of any of examples 14-15 wherein determining a charging parameter includes generating a battery assessment as a function of the multiple battery parameters and matching the battery assessment to one of multiple charging profiles.

17. The device of example 16 wherein the battery assessment includes values for a number of charging and discharging cycles of the battery.

18. The device of any of examples 16-17 wherein matching is performed using a similarity measure between the battery assessment and the assessments associated with the charging profiles, wherein the similarity measure comprises at least one of cosine similarity, Manhattan distance, Euclidean distance, Minkowski distance, and Jaccard similarity.

19. A device includes a processor and a memory device coupled to the processor and having a program stored thereon for execution by the processor to perform operations. The operations include detecting a request for a battery charge, receiving multiple battery parameters representative of battery charging history, determining a charging parameter to increase battery life as a function of the multiple battery parameters, and charging the battery in accordance with the charging parameter.

20. The device of example 19 wherein determining a charging parameter includes generating a battery assessment as a function of the multiple battery parameters and matching the battery assessment to one of multiple charging profiles.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims.

1. A method comprising:
detecting a request for a battery charge;
receiving multiple battery parameters representative of battery charging history;
determining a charging parameter to increase battery life as a function of the multiple battery parameters; and
charging the battery in accordance with the charging parameter.

2. The method of claim 1 wherein the request includes a requested current.

3. The method of claim 1 wherein the multiple battery parameters are stored on a storage device on the battery or a remote storage device.

4. The method of claim 1 wherein the charging parameter comprises a current level.

5. The method of claim 1 wherein the charging parameter comprises a voltage level.

6. The method of claim 1 wherein determining a charging parameter comprises:
generating a battery assessment as a function of the multiple battery parameters; and
matching the battery assessment to one of multiple charging profiles.

7. The method of claim 6 wherein the battery assessment includes values for a number of charging and discharging cycles of the battery.

8. The method of claim 7 wherein the battery assessment includes values for one or more of actual calendar aging, predicted calendar aging, temperature ranges for actual, maximum, minimum, average, and predicted, state of charge ranges for actual, maximum, minimum, average, and predicted.

9. The method of claim 6 wherein matching is performed using a similarity measure between the battery assessment and the assessments associated with the charging profiles.

10. The method of claim 9 wherein the similarity measure comprises at least one of cosine similarity, Manhattan distance, Euclidean distance, Minkowski distance, and Jaccard similarity.

11. The method of claim 1 wherein determining a charging parameter comprises matching the battery parameters to one of multiple charging profiles having associated charging profile battery parameters using a similarity measure.

12. The method of claim 11 wherein the similarity measure comprises at least one of cosine similarity, Manhattan distance, Euclidean distance, Minkowski distance, and Jaccard similarity.

13. The method of claim 1 wherein increasing battery life comprises increasing the number of charging and discharging cycles of the battery.

14. A machine-readable storage device having instructions for execution by a processor of a machine to cause the processor to perform operations to perform a method, the operations comprising:
detecting a request for a battery charge;
receiving multiple battery parameters representative of battery charging history;
determining a charging parameter to increase battery life as a function of the multiple battery parameters; and
charging the battery in accordance with the charging parameter.

15. The device of claim 14 wherein the request includes a requested current, wherein the multiple battery parameters are stored on a storage device on the battery or a remote storage device, wherein the charging parameter comprises at least one of a current level and a voltage level.

16. The device of claim 14 wherein determining a charging parameter comprises:
generating a battery assessment as a function of the multiple battery parameters; and
matching the battery assessment to one of multiple charging profiles.

17. The device of claim 16 wherein the battery assessment includes values for a number of charging and discharging cycles of the battery.

18. The device of claim 16 wherein matching is performed using a similarity measure between the battery assessment and the assessments associated with the charging profiles, wherein the similarity measure comprises at least one of cosine similarity, Manhattan distance, Euclidean distance, Minkowski distance, and Jaccard similarity.

19. A device comprising:
a processor; and
a memory device coupled to the processor and having a program stored thereon for execution by the processor to perform operations comprising:
detecting a request for a battery charge;
receiving multiple battery parameters representative of battery charging history;
determining a charging parameter to increase battery life as a function of the multiple battery parameters; and
charging the battery in accordance with the charging parameter.

20. The device of claim 19 wherein determining a charging parameter comprises:
generating a battery assessment as a function of the multiple battery parameters; and
matching the battery assessment to one of multiple charging profiles.
